(19) United States
(12) Patent Application Publication
(10) Pub. No.: US 2026/0223425 A1
(43) Pub. Date: Jul. 30, 2026

(54) A METHOD FOR THE MANUFACTURE OF A GRAPHENE-CONTAINING LAMINATE

(71) Applicant: PARAGRAF LIMITED, Somersham (GB)

(72) Inventors: Ivor Guiney, Somersham (GB); Andrew N. Macinnes, Somersham (GB)

(73) Assignee: PARAGRAF LIMITED, Somersham (GB)

(21) Appl. No.: 19/157,898

(22) PCT Filed: Feb. 13, 2024
(86) PCT No.: PCT/EP2024/053650

§ 371 Date: Aug. 19, 2025

(30) Foreign Application Priority Data
Feb. 20, 2023 (GB) 2302406.0

(51) Int. Cl. H10D 62/80; C23C 16/26; H10D 48/36

(52) U.S. Cl. CPC H10D 62/882; C23C 16/26; H10D 48/362

(57) ABSTRACT

There is provided a method for the manufacture of a graphene-containing laminate (240), the method comprising: (i) providing a first wafer (220) comprising a first layer (205) on a first silicon support (200), wherein the first layer (205) is a dielectric layer and has an exposed growth surface (205′) distal from the first silicon support (200), wherein the first layer (205) has a first region (205c) extending at least 2 nm down from the exposed growth surface (205′) which satisfies the following: a) 210-a dislocation density of less than 5,000 cm−2 as measured by TEM; and b) a surface roughness (Ra) of less than 1 nm as measured by AFM; (ii) providing a second wafer (235) comprising a second layer (230), wherein the second layer (230) has an exposed contact surface (230′); (iii) forming a graphene layer structure (210) on the exposed growth surface of the first layer by CVD; (iv) wafer-bonding the first wafer (220) to the exposed contact surface (230′) of the second layer (230) to sandwich the graphene layer structure (210) between the first silicon support (200) and the second layer (230); and (v) removing the first silicon support (200) to leave a retained portion of the first layer (205) formed from the first region (205c) and having a thickness of less than 20 nm.

The present invention relates to a method for the manufacture of a graphene-containing laminate, and a graphene-containing laminate and an electronic device obtainable therefrom. More particularly, the present invention relates to a method which comprises forming a graphene layer structure by CVD directly on a non-metallic surface of a wafer whereby a layer of the wafer providing the non-metallic surface remains incorporated in the resulting graphene-containing laminate, such that an electronic device including said layer may be manufactured therefrom.

Two-dimensional (2D) materials, in particular graphene, are currently the focus of intense research and development worldwide. 2D-materials have been shown to have extraordinary properties, both in theory and in practice which has led to a deluge of products incorporating such materials which include coatings, batteries and sensors to name but a few. Graphene is most prominent and is being investigated for a range of potential applications. Most notable is the use of graphene in electronic devices and their constituent components and includes transistors, diodes, LEDs, photovoltaic cells, Hall-effect sensors, current sensors, biosensors and the like.

Accordingly, there are a wide range of electronic devices known in the prior art which have integrated graphene layer structures (single layer or multi-layer graphene) and/or other 2D-materials as key materials for delivering improvements in such devices over earlier devices and electronic products. These include structural improvements through the use of thinner and lighter materials (which can give rise to flexible electronics) as well as performance improvements such as increased electrical and thermal conductance leading to greater operating efficiencies.

The preparation of sufficiently large area graphene with high uniformity has been major problem in the art which has hindered the uptake of graphene in commercial processes and ultimately electronic devices. The standard in the art is to manufacture graphene by CVD on copper foils or other catalytic metal substrates. A significant proportion of research and development has since focussed on the need to optimise the process by which graphene is transferred from such substrates to those of interest for electronic devices (i.e. non-metallic substrates, for example semiconductors such as silicon and insulators such as sapphire).

However, the inventors found that graphene grown on copper is inevitably contaminated, if not with copper, at least with the additional materials which are essential to effect the transfer. These include transfer polymers such as PMMA, metal etchants and solvents to remove the polymer. Polymer residues are however never fully removed and graphene provided by such methods cannot be devoid of transfer polymers and/or copper. Additionally, the physical manipulation of the graphene during transfer leads to defects in the atomically thin material.
Nanomaterials, 2021, 11, 2837 “Graphene Transfer: A Physical Perspective” provides a recent review of graphene transfer methods.
Nature Communications, 2021, 12, 917 “Large-area integration of two-dimensional materials and their heterostructures by wafer bonding” relates to a method of transferring CVD graphene from copper foils to silicon wafers.
Adv. Mater. Technol. 2023, 2201587 “Assessment of Wafer-Level Transfer Techniques of Graphene with Respect to Semiconductor Industry Requirements” is a recent example graphene transfer techniques at wafer-scale, both of which are observed to result in appreciable copper contamination.
US 2013/240839 A1 relates to graphene-channel based devices and techniques for the fabrication thereof which may include a wafer bonding step to form an oxide-to-oxide bond between an oxide coated graphene layer and a counterpart CMOS device wafer.
US 2013/256629 A1 relates to a graphene semiconductor device and a method of manufacturing a graphene semiconductor device which may include attaching a semiconductor layer of a laminate further comprising a sacrificial substrate and a sacrificial layer therebetween to a surface of a graphene layer and etching the sacrificial layer in order to remove the sacrificial substrate.

It is also known in the art that graphene may be synthesised, manufactured, formed, directly on non-metallic surfaces of substrates. The present inventors have found that the most effective method for manufacturing high-quality graphene, especially directly on such non-metallic surfaces, is that disclosed in WO 2017/029470 (the contents of which is incorporated herein by reference), which provides two-dimensional materials, particularly graphene, with a number of advantageous characteristics including very good crystal quality, large material grain size, minimal material defects, large sheet size and no metal or organic polymer contamination. The method of WO 2017/029470 may be performed using vapour phase epitaxy (VPE) systems and metal-organic chemical vapour deposition (MOCVD) reactors.

Whilst the method of WO 2017/029470 enables the production of high-quality graphene with excellent uniformity and a constant number of layers (as desired) across its whole area on the substrate without additional carbon fragments or islands, the inventors have found that this introduces problems with the formation of dielectric layers on the graphene (for example, by atomic layer deposition). Such problems are not encountered in the prior art where graphene is transferred due to the inevitable presence of defects which act as nucleation sites. As such, the inventors have found that there is a significantly greater challenge associated with dielectric layer formation on the pristine surface of CVD-grown graphene.

WO 2022/175273 (the contents of which is incorporated herein by reference in its entirety), as well as the corresponding GB 2603905 and TW 202246175, is a publication originating from the present inventors which relates to the formation of a thin graphene-containing conductive substrate obtainable by etching a sacrificial silicon wafer away from a graphene layer structure formed on an insulative layer that is itself formed on the silicon wafer.
US 2011/068320 A1 relates to an electronic device that includes an under-layer constructed of highly ordered crystalline material having a high dielectric constant and an over-layer constructed of a crystalline material having a high dielectric constant, and a layer of graphene located between the over-layer and the under-layer. This document does not disclose a method of manufacture but discloses that these layers can be formed on a substrate material.
WO 2022/200351 A1 relates to a method of forming a graphene layer structure by CVD on specific growth surfaces of substrates, in particular YSZ.
US 2012/175594 A1 relates to semiconductor structures, and particularly to local dual gate graphene based devices and methods of manufacturing the same.
US 8785261 B relates to the field of microelectronic transistor fabrication and, more particularly, to forming a graphene layer as a channel layer for a microelectronic transistor.
JP 2010153793 A (and corresponding US 2010/200839A1 ) relates to graphene for use in electronic and optical device applications, more particularly, to substrates having a graphene layer grown thereon, and electro-optical integrated circuits formed in such a substrate.

The present invention aims to overcome, or at least reduce, the aforementioned combination of problems in the prior art so as to allow for the wafer-scale integration of high-quality, defect and contamination free, graphene and high-quality dielectrics into electronic devices, or to at least provides a commercially viable alternative thereto.

In a first aspect, the present invention provides a method for the manufacture of a graphene-containing laminate, the method comprising:
(i) providing a first wafer comprising a first layer on a first silicon support, wherein the first layer is a dielectric layer and has an exposed growth surface distal from the first silicon support, wherein the first layer has a first region extending at least 2 nm down from the exposed growth surface which satisfies the following:
   a) a dislocation density of less than 5,000 cm⁻² as measured by TEM; and
   b) a surface roughness (Ra) of less than 1 nm as measured by AFM;
(ii) providing a second wafer comprising a second layer, wherein the second layer has an exposed contact surface;
(iii) forming a graphene layer structure on the exposed growth surface of the first layer by CVD, and optionally forming a further layer comprising dielectric material on the graphene layer structure;
(iv) wafer-bonding the first wafer to the exposed contact surface of the second layer to sandwich the graphene layer structure between the first silicon support and the second layer; and
(v) removing the first silicon support, and optionally a portion of the first layer, to leave a retained portion of the first layer formed from the first region and having a thickness of less than 20 nm.

The present disclosure will now be described further. In the following passages, different aspects/embodiments of the disclosure are defined in more detail. Each aspect/embodiment so defined may be combined with any other aspect/embodiment or aspects/embodiments unless clearly indicated to the contrary. In particular, any feature indicated as being preferred or advantageous may be combined with any other feature or features indicated as being preferred or advantageous.

The present invention relates to a method for the manufacture of a graphene-containing laminate. As described in greater detail herein, the graphene-containing laminate comprises a silicon support having thereon, a graphene layer structure that is sandwiched between primary and secondary dielectric layers. As such, there are no intervening layers between any given layer said to be “on” another layer. Graphene is a very well-known two-dimensional material referring to an allotrope of carbon comprising a single layer of carbon atoms in a hexagonal lattice. A graphene layer structure, as used herein, refers to one or more layers of graphene. Accordingly, the present invention relates to the formation of a monolayer of graphene as well as multilayer graphene. A graphene layer structure preferably has from 1 to 10 monolayers of graphene. In many subsequent applications of a graphene-containing laminate for forming an electronic device, one monolayer of graphene is particularly preferred. Accordingly, the graphene layer structure is preferably a graphene monolayer. Nevertheless, multilayer graphene may be preferable for certain applications and 2 or 3 layers of graphene may be preferred.

In the first steps, both a first wafer and a second wafer are provided. Within the art of semiconductor electronics manufacturing, a wafer is a well-known term which may be used synonymously with, for example, a substrate. A wafer is typically predominantly formed of silicon and may then have layers of thin films deposited thereon and etched so as to fabricate electronic devices and integrated circuits.

The first wafer described herein comprises a first layer on a first silicon support, wherein the first layer is a dielectric layer. The second wafer comprises a second layer which is preferably provided on a second silicon support, wherein the second layer of the second wafer provides an exposed contact surface (i.e. an exposed surface which is used to contact the first wafer in a subsequent step).

Throughout the present description, “first”, “second”, “primary”, “secondary” etc. may be used to describe various layers and/or supports, though it will be appreciated that the features are not limited by these terms, but are only used to distinguish one layer and/or support from another layer and/or support.

The second wafer may consist of the second layer (i.e. may be a single material, including silicon) or consist of the second layer on the silicon support. As described herein, preferably the first and second layers are non-metallic, preferably dielectric layers, and may consist of a single material or may be formed of multiple sub-layers.

The second wafer may be described as a target wafer or target substrate onto which the graphene layer structure is transferred and is therefore not particularly limited. The second wafer is that which may be incorporated into an electronic device manufacture from the resulting graphene-containing laminate. As such, the second wafer preferably comprises a silicon support and/or may be a “CMOS” wafer. Such a wafer is typically a silicon wafer which has associated circuitry embedded within the wafer. The second wafer may also comprise regions or channels of embedded materials, for example waveguide materials, such as silicon nitride embedded within silicon dioxide, which are suitable for electro-optic modulators and photodetectors. The exposed contact surface of the second layer may also be formed of regions of different materials. For example a silicon support may have a surface comprising a patterned region(s) of the silicon and region(s) of embedded dielectric material. Such a wafer may be suitable for the manufacture of a graphene barristor. The silicon support may preferably be a “pure” silicon support (essentially consisting of silicon, doped or undoped). Where the second wafer comprising the second layer further comprises a second silicon support, the exposed contact surface of the second layer is distal from the second silicon support (the opposite non-exposed surface of the second layer being that which is contact with the support).

Since the second wafer is not particularly limited, it is advantageous that the second wafer can comprise metal contacts at the exposed second surface (together with the associated circuitry embedded in the second layer, and optionally the underlying support). This is particularly beneficial where a CVD grown graphene layer structure is employed since growth by MOCVD processes as described herein, but directly onto metallic contacts rather than a non-metallic surface, is not desirable. As such, the method allows for the incorporation of graphene formed by such methods into devices having underlying contacts.

The first wafer may be said to comprise a sacrificial silicon support in view of the subsequent method steps. As such, the silicon support may preferably be a “pure” silicon support. Similar to the second wafer, the first layer of the first wafer has an exposed growth surface distal from the first silicon support. The term “growth” serves to refer to the exposed surface upon which graphene is formed (i.e. grown) directly thereon by CVD.

The thickness of a silicon support layer is generally much thicker that the thickness of the layer thereon. When and where present, the support layer typically has a thickness of 250 μm to 1.5 mm, for example from 400 μm to 1 mm. On the other hand, the thickness of a layer thereon is substantially thinner. Preferably, the thickness of such layer is at least 2 nm, preferably at least 5 nm and/or less than 500 nm, preferably less than 100 nm. Suitable ranges for the thickness of the layer are preferably 5 nm to 100 nm, preferably 10 to 50 nm. In some embodiments, very thin layers are preferred and the thickness of the layer may preferably be from 2 nm to 10 nm. In some embodiments, the first and/or second layer does not comprise the native silicon oxide which may be removed from the surface of the silicon support before forming the layer.

In the present invention, the first layer also has a first region extending at least 2 nm down from the exposed growth surface which satisfies the following: a) a dislocation density of less than 5,000 cm⁻² as measured by transmission electron microscopy (TEM); and b) a surface roughness (Ra) of less than 1 nm as measured by atomic force microscopy (AFM).

The inventors have found that the uppermost region of a first layer formed on a silicon support is of the highest quality which generally improves with increasing thickness and therefore the most desirable for the formation of graphene thereon. A first layer may be grown to a sufficient thickness, and if necessary, through the use of sub-layers, in order to reduce the number of dislocations in the crystalline (sub)-layer that is subsequently formed to provide the first region. The first region generally consists of a single material though may also be multilayer. As described herein, buffer layers may be employed in order to reduce the lattice mismatch between silicon and the desired material that forms the first region. In other embodiments, the first layer (and therefore the first region) consists of a single material and may be grown thicker whereby the density of dislocations originating at the interface with the silicon support reduces further from the interface. Preferably the first layer has a thickness of from 2 nm to 500 nm, preferably from 5 nm to 100 nm.

Therefore, the first region is characterised by at least a portion of the first layer (that may be the entire first layer) which has a thickness of at least 2 nm. The dislocation density serves to characterise the high degree of single crystallinity of the first region and may be measured using conventional techniques which are known to those skilled in the art such as TEM (e.g. cross-sectional TEM). Whilst lower dislocation densities are generally preferred, such as less than 4,000cm⁻², or less than 2,000cm⁻², a minimal number of dislocations may still be desired since, without wishing to be bound by theory, these defect sites at the exposed surface of the first layer are believed to provide sites for graphene nucleation by CVD. Accordingly, a minimal defect density may be at least 1cm⁻², at least 10 cm⁻² or at least 100 cm⁻².

The first region also has a surface roughness of less than 1 nm, which may again be measured by conventional techniques which are known to those skilled in the art such as AFM. As will be appreciated, this a measurement of the exposed growth surface of the first layer. Such a low surface roughness facilitates the formation of high-quality graphene by CVD. In some embodiments, the surface roughness may be less than 0.8 nm, or less than 0.6 nm. Surface roughness as used herein refers to the arithmetic average roughness, known as Ra.

Preferably the first region of the first layer extends at least 5 nm down from the exposed growth surface, preferably at least 10 nm, preferably at least 20 nm. A dislocation density is a parameter which is known in the art, though is typically used to characterise significantly thicker layers (for example GaAs layers in LED structures). Dislocation density is often measured by XRD which provides an average dislocation density across the entire layer (which can be multiple micrometers thick). In the above example of GaAs, the dislocation density across the entire layer is important for the properties of final device. On the contrary, the present invention utilises a much thinner uppermost region which is retained in the final laminate. TEM is a measurement technique which allows for the measurement of the dislocation density proximal to the surface of the layer, though practically it becomes challenging to accurately measure the dislocation density in regions of less than 2 nm. As such, characterising the first region at a thickness of at least 10 nm, for example, is preferred. Since the portion of the first layer retained in the resulting laminate is 20 nm or less, it is sufficient for the first region to extend up to 20 nm (e.g. from 2 nm to 20 nm or from 10 nm to 20 nm) down from the exposed growth surface (though may of course extend further).

As described herein, the method may comprise removing a portion of the first layer (and optionally the first region) in order to provide a thin layer of dielectric of less than 20 nm. In some preferred embodiments, the thickness of the first layer and/or the first region thereof are such that the method does not involve removing a portion subsequently. For example, a first layer formed of a single material may have a thickness of about 5 nm, the entirety of the first layer meeting the requirements of the first region and the entire layer may be used as a layer in a final device without having to remove a portion thereof in the later steps described herein.

Dielectric materials for use in semiconductor fabrication processes are well-known. The particular material of the first layer, and-where the second layer comprises a dielectric material-the second layer, is not particularly limited whereby the layer provides a first region having the desired dislocation density and surface roughness. The first layer is formed of a dielectric material suitable for the subsequent CVD formation of graphene. As such, it is preferred that the first region of the first layer is formed of aluminium nitride, magnesium fluoride, calcium fluoride, yttria-stabilised zirconia (YSZ), yttria-stabilised hafnia (YSH) and/or rare-earth oxide since the inventors have found such materials to provide desirably high crystallinity and uniformity, but also provide a particular benefit for facilitating the growth of a high-quality graphene layer structure. Preferably the first layer is formed by molecular beam epitaxy and/or high temperature sputtering. Such methods typically employ high temperatures, for example, from about 500° C. to about 1000° C.

In some preferred embodiments, the growth surface has a <111> crystallographic orientation. The inventors have found that such an orientation, especially for the preferred dielectric materials described above such as YSZ, YSH and the rare-earth oxides, is particularly suitable for the formation of high-quality graphene by CVD. A <111> growth surface may be achieved through epitaxial growth on a <111> surface of a silicon wafer. The inventors have found that a <111> orientation is preferable for graphene epitaxy since it provides a lower energy orientation and is more stable to higher temperatures than <100>, for example. They were surprised to find that improved graphene crystallinity could be obtained on <111> which, without wishing to be bound by theory, is believed to result from the threefold rotational symmetry which lends itself to better growth of hexagonal two-dimensional crystals of graphene. Scandium oxide is one example of a particularly preferred dielectric material and may be formed with the desired dislocation density and surface roughness without the use of a buffer layer. Moreover, the inventors were surprised to find that these materials are unexpectedly stable to the high temperatures required for CVD such that the dislocation density and the surface roughness at the interface of the resulting graphene are substantially the same after CVD allowing the high-quality dielectric layer to be incorporated into a final device, particularly for its electrical properties.

In some preferred embodiments, the first layer comprises a buffer layer directly on the first silicon support. The first layer may consist of a buffer layer and a further layer whereby the first region is provided the further layer. A buffer layer may help to mitigate the differences in lattice parameters and reduce the risk of forming defects in the first region of the layer. A buffer layer is an inorganic cubic material, generally a metal oxide, though CaF₂ and MgF₂ may also be preferred. Suitable metal oxides include zirconium, yttrium, hafnium, cerium, erbium, gadolinium, dysprosium, praseodymium and/or magnesium oxide, strontium titanate (STO) and/or yttria-stabilised zirconia (YSZ). Particularly preferred oxides for forming a buffer oxide layer are erbium oxide, yttrium oxide, zirconium oxide, or a combination thereof, due to their thermodynamic stability during subsequent CVD growth of graphene. The buffer layer may be formed of one or more sub-layers of such materials.

Without wishing to be bound by theory, the ZrO₂ or YSZ interface with Si is believed to be less chemically stable than the Er₂O₃, Y₂O₃ or Sc₂O₃ interface with Si due to a greater driving force for the formation of secondary phases, e.g. silicides such as ZrSi or silicates such as ZrSiO₄, providing an advantage for erbium and/or yttrium oxide as a buffer layer, particularly as the layer directly on the silicon in the case of a multilayer buffer layer. Indeed, it is also a particular advantage of the invention wherein the scandium oxide is directly on the silicon support layer since the inventors have found that interface between scandium oxide and silicon is the most chemically stable of these oxides. It is also believed that scandium oxide deposited directly on silicon as described herein may form an interface of scandium suboxide mitigating the differences in lattice parameter allowing for high crystal quality and/or a 7×7 reconstruction of the silicon heated under vacuum with the oxide removed produces a silicon surface with a different effective unit cell dimensional which may match better with scandium oxide. Erbium oxide has an advantage over other oxides in that it has better thermodynamic stability on silicon while being about the same in terms of lattice matching. One problem with erbium oxide is that it is strongly paramagnetic unlike other oxides which can be a problem for the intended final electronic device manufactured from the resulting graphene substrate.

In some preferred embodiments, the buffer layer consists of a single material. Of secondary consideration is the lattice mismatch between silicon, the layers of the first layer. For example, where the first region is provided by scandium oxide, YSZ has a small lattice mismatch between both silicon and scandium oxide. That is, the lattice constant for silicon is 5.43 Å and the lattice constant for scandium oxide is 9.85 Å (where half of the lattice constant is about 4.93 Å). The lattice constant for zirconium oxide is 5.15 Å, and YSZ is about 5.13 Å (depending on the extent of yttria doping), which give rise to an even lattice mismatch between silicon and scandium oxide of about 5% and about 4%, respectively. The corresponding mismatches for yttrium oxide (which has a lattice constant of 5.30 Å) are about 2% and about 7%. However, the inventors have found that pure binary zirconium oxide can be unstable to phase changes between its cubic and tetragonal phases at the temperatures desired for CVD growth of graphene. YSZ is also less thermodynamically stable than the other preferred rare earth oxides (Er, Y and Sc) and therefore YSZ buffer layers may not be suitable at very high graphene deposition temperatures, e.g. above 1,250° C. It is believed that by using a very thin layer of zirconium oxide (or YSZ), e.g. less than 10 nm, preferably less than 5 nm, more preferably less than 2 nm, the zirconium oxide layer is advantageously more resistant to phase changes. Combinations of these oxides may be used, for example a layer of yttrium oxide may be formed on the silicon, followed by a layer of zirconium oxide or YSZ to form a multilayer buffer layer. Buffer layers can have a drawback in that multiple layers having different thermal stabilities and coefficients of expansion can increase the risk of delamination.

Whilst the advantage of scandium oxide for graphene growth arises from its chemical stability, low surface energy and stability to roughening at high temperatures, and in particular its surface crystal orientation, without wishing to be bound by theory, it is also believed that the lattice constant for scandium oxide being a substantially precise multiple of that of graphene (i.e. 2.46 Å where 4×2.46 Å =9.84 Å) further assists in the formation of high quality graphene.

The buffer layer, when present, may have a thickness of least 2 nm, preferably at least 5 nm. Preferred ranges for the thickness of the buffer layer are 2 nm to 20 nm, more preferably up to 10 nm. In some embodiments, the first region may not form part of the buffer layer.

The present inventors unexpectedly found that a growth surface formed of the preferred materials described herein such as scandium oxide were advantageous for graphene growth by CVD. Without wishing to be bound by theory, the inventors believe that they have a particularly low carbon solubility at high temperatures (relative to known growth substrate materials) such that during the high temperatures of CVD, high-quality uniform graphene may be grown without the defects which can be present when grown directly on other known growth surfaces. For example, it is known that growth surfaces formed of materials such as silicon or III-V semiconductors risk giving rise to covalent bonding to the carbon atoms during growth resulting in graphene defects.

The method comprises a step of forming a graphene layer structure on the exposed growth surface of the first layer by CVD. CVD refers generally to a range of chemical vapour deposition techniques, each of which involve deposition to produce thin film materials such as two-dimensional crystalline materials like graphene. Volatile precursors, those in the gas phase or suspended in a gas, are decomposed to liberate the necessary species to form the desired material, carbon in the case of graphene. CVD as described herein is intended to refer to thermal CVD such that the formation of graphene from the decomposition of a carbon-containing precursor is the result of the thermal decomposition of said carbon-containing precursor. Forming may be considered synonymous with synthesising, manufacturing, producing, depositing and growing.

Preferably, the method involves forming graphene by thermal CVD such that decomposition is a result of heating the carbon-containing precursor. Preferably, the temperature of the growth surface during CVD is from 700° C. to 1350° C., preferably from 800° C. to 1250° C., more preferably from 1000° C. to 1250° C. The inventors have found that such temperatures are particularly effective for providing graphene growth directly on first wafer by CVD. Preferably, the CVD reaction chamber used in the method disclosed herein is a cold-walled reaction chamber wherein a heater coupled to the wafer is the only source of heat to the chamber.

In a particularly preferred embodiment, the CVD reaction chamber comprises a close-coupled showerhead having a plurality, or an array, of precursor entry points. Such CVD apparatus comprising a close-coupled showerhead may be known for use in MOCVD processes. Accordingly, the method may alternatively be said to be performed using an MOCVD reactor comprising a close-coupled showerhead. In either case, the showerhead is preferably configured to provide a minimum separation of less than 100 mm, more preferably less than 25 mm, even more preferably less than 10 mm, between the surface of the substrate/wafer and the plurality of precursor entry points. As will be appreciated, by a constant separation it is meant that the minimum separation between the surface of the substrate and each precursor entry point is substantially the same. The minimum separation refers to the smallest separation between a precursor entry point and the substrate surface. Accordingly, such an embodiment involves a “vertical” arrangement whereby the plane containing the precursor entry points is substantially parallel to the plane of the substrate surface (i.e. the growth surface of the first wafer).

The precursor entry points into the reaction chamber are preferably cooled. The inlets, or when used, the showerhead, are preferably actively cooled by an external coolant, for example water, so as to maintain a relatively cool temperature of the precursor entry points such that the temperature of the precursor as it passes through the plurality of precursor entry points and into the reaction chamber is less than 100° C., preferably less than 50° C. For the avoidance of doubt, the addition of precursor at a temperature above ambient does not constitute heating the chamber, since it would be a drain on the temperature in the chamber and is responsible in part for establishing a temperature gradient in the chamber.

Preferably, a combination of a sufficiently small separation between the growth surface and the plurality of precursor entry points and the cooling of the precursor entry points, coupled with the heating of the growth surface to with a decomposition range of the precursor, generates a sufficiently steep thermal gradient extending from the surface to the precursor entry points to allow graphene formation on the surface. As disclosed in WO 2017/029470, very steep thermal gradients may be used to facilitate the formation of high-quality and uniform graphene directly on such non-metallic substrates, preferably across the entire surface of the substrate. The substrate/wafer may have a diameter of at least 5 cm (2 inches), at least 15 cm (6 inches) or at least 30 cm (12 inches). Particularly suitable apparatus for the method described herein include an Aixtron@ Close-Coupled Showerhead® reactor and a Veeco® TurboDisk reactor.

Consequently, in a particularly preferred embodiment wherein the method of the present invention involves using a method as disclosed in WO 2017/029470, forming the graphene layer structure on the growth surface by CVD comprises:
providing the first wafer on a heated susceptor in a close-coupled reaction chamber, the close-coupled reaction chamber having a plurality of cooled inlets arranged so that, in use, the inlets are distributed across the growth surface and have constant separation from the first wafer;
cooling the inlets to less than 100° C.;
introducing a carbon-containing precursor in a gas phase and/or suspended in a gas through the inlets and into the close-coupled reaction chamber; and
heating the susceptor to achieve a growth surface temperature of at least 50° C. in excess of a decomposition temperature of the precursor, to provide a thermal gradient between the growth surface and inlets that is sufficiently steep to allow the formation of graphene from carbon released from the decomposed precursor;
wherein the constant separation is less than 100 mm, preferably less than 25 mm, even more preferably less than 10 mm.
In another particularly preferred embodiment wherein the method involves using a method as disclosed in WO 2019/138231 (the contents of which is incorporated herein in its entirety), forming the graphene layer structure on the growth surface by CVD comprises:
providing the first wafer on a heated susceptor in a reaction chamber, the reaction chamber having a plurality of inlets arranged so that, in use, the inlets are distributed across the growth surface and have constant separation from the first wafer;
rotating the heated susceptor at a rotation rate of at least 600 rpm, preferably up to 3000 rpm;
introducing a carbon-containing precursor in a gas phase and/or suspended in a gas through the inlets and into the reaction chamber; and
heating the susceptor to achieve a growth surface temperature of at least 50° C. in excess of a decomposition temperature of the precursor;
wherein the constant separation is at least 12 cm, preferably up to 20 cm.

The most common carbon-containing precursor in the art for graphene growth is methane (CH₄). The inventors have found that it is preferable that the carbon-containing precursor used to form graphene is an organic compound, that is, a chemical compound, or molecule, that contains a carbon-hydrogen covalent bond, which comprises two or more carbon atoms. Such precursors have a lower decomposition temperature than methane which advantageously allows the growth of graphene at lower temperatures when using the method described herein which is particularly advantageous for growth on such non-metallic surfaces. Preferably, the precursor is a liquid when measured at 20° C. and 1 bar of pressure (i.e. under standard conditions according to IUPAC). Accordingly, the precursor has a melting point that is below 20° C., preferably below 10° C., and has a boiling point above 20° C., preferably above 30° C. Liquid precursors are simpler to store and handle when compared to gaseous precursors which typically require high pressure cylinders. Due to their relatively reduced volatility when compared to gaseous precursors, they present a lower safety risk during large scale manufacture. Increasing the molecular weight of the compounds beyond about C₁₀, particularly beyond about C₁₂, typically reduces their volatility and suitability for CVD growth of graphene on non-metallic substrates (though graphene can be produced from solid organic compounds). Preferably, the organic compound consists of carbon and hydrogen and, optionally, oxygen, nitrogen, fluorine, chlorine and/or bromine.

As discussed above, the method described herein preferably uses a carbon-containing precursor that is an organic compound comprising two of more carbon atoms, i.e. a C₂₊ organic compound. Preferably, the carbon-containing precursor is a C₃-C₁₂ organic compound consisting of carbon and hydrogen and, optionally, oxygen, nitrogen, fluorine, chlorine and/or bromine. As described herein, a Cₙ organic compound refers to one comprising “n” carbon atoms and optionally one or more further hetero atoms oxygen, nitrogen, fluorine, chlorine and/or bromine. Preferably, the organic compound comprises at most one heteroatom as such organic compounds are typically more readily available in high purity, for example ethers, amines, and haloalkanes.
The carbon-containing precursor is preferably a C₃-C₁₀ organic compound consisting of carbon and hydrogen and, optionally, oxygen, nitrogen, fluorine, chlorine and/or bromine, even more preferably a C₆-C₉ organic compound. In a preferred embodiment, the precursor does not comprise a heteroatom, such that the precursor consists of carbon and hydrogen. In other words, preferably the carbon-containing precursor is a hydrocarbon, preferably an alkane.

It is also preferable that the organic compound comprise at least two methyl groups (—CH3). Particularly preferred organic compounds for use as carbon-containing precursors, and methods of forming graphene therefrom by CVD, are described in GB 2604377 (the contents of which is incorporated herein in its entirety). The inventors have found that when forming graphene directly on non-metallic substrates, precursors beyond the traditional hydrocarbons methane and acetylene allow for the formation of even higher quality graphene. Preferably, the precursor is a C₄-C₁₀ organic compound, more preferably the organic compound is branched such that the organic compound at least three methyl groups.

Without wishing to be bound by theory, the inventors believe that heavier organic compounds (i.e. those greater than C₁₂, or greater than C₁₀, and/or those which are solid under standard conditions) provide a “less pure” source of CH₃ radicals. With an increase in size and complexity of the organic compound there is an increase in the number of decomposition pathways and the possibility of a greater range of by-products which can lead to graphene defects. The organic compounds as described herein provide a balance of being large enough to deliver the required, and a desirably high fraction of, methyl groups under pyrolysis. The organic compounds are however small enough to be simple to purify, particularly where the precursor is liquid, and have a relatively simple pyrolysis chemistry with limited decomposition pathways. Furthermore, unlike heavier compounds, they do not so readily condense within the reactor plumbing which is a particular disadvantage for the industrial production of graphene due to the greater risk of reactor downtime.

In some embodiments, the method further comprises forming a further layer comprising dielectric material on the graphene layer structure. In other embodiments, no further layer is formed on the graphene layer structure which can be advantageous since this can allow for the formation of Van der Waals heterostructures through the following steps of transferring the graphene onto a suitable layer of the second wafer.

One advantage of the present invention lies in the provision of a high-quality dielectric on pristine graphene through having avoided the need to form the layer on graphene. However, the present invention still allows for the formation of a further layer on the graphene prior to the wafer-bonding step since the further layer subsequently simply forms part of the underlying support after having been “flipped”. As described herein for the first and second layers, the further layer may comprise one or more sub-layers.

The inventors have found that a further layer may be formed on the graphene layer structure so as to dope the graphene. The further layer preferably comprises a dielectric metal oxide, preferably molybdenum oxide. Molybdenum oxide is a particularly preferred material that the inventors have found is suited for counter doping CVD-grown graphene (which is typically n-type whereas the intrinsic doping of transferred graphene is typically p-type due to exposure to catalytic metal substrates and/or transfer polymers and/or wet processing chemicals).

The thickness of such a layer is preferably less than 5 nm, more preferably less than 3 nm, for example from 0.1 nm to 5 nm. The inventors have found that this thickness may be used to control the extent of doping of the graphene layer structure to arrive the desired charge carrier concentration whereby a greater thickness leads to more p-doping. The desired nominal thickness can be achieved through use of a Quartz Crystal Microbalance (QCM) during formation which provides the skilled person with an in-situ measurement of the amount of material deposited when carrying out the method. The thickness of the layer is therefore a mean average thickness of the layer. The thickness may then equally be readily determined by those skilled in the art using conventional techniques, for example AFM. The further layer may be deposited using conventional means in the art, for example PVD techniques such as sputtering or evaporation (e.g. thermal evaporation).

Preferably, the graphene layer structure has a charge carrier concentration of less than 5×10¹² cm⁻², preferably less than 2×10¹² cm⁻² , more preferably less than 10¹² cm⁻² , as a result of the combination of materials and method of manufacture described herein. The charge carrier concentration is that measured at ambient conditions (e.g. 25° C.) after manufacture is complete. A device may be manufactured incorporating the graphene-containing laminate and, as such, the charge carrier concentration refers to that of the final, as-manufactured laminate or device.

The method further comprises a step of wafer-bonding the first wafer to the exposed contact surface of the second layer to sandwich the graphene layer structure between the first silicon support and the second layer. Accordingly, the exposed contact surface provided by the second layer of the second wafer is contacted with the uppermost layer (e.g. the exposed graphene layer structure or a further layer formed thereon) to bond the two wafers.

The method may further comprise a step of patterning the first and/or second wafers described hereinabove, in particular the layers provided on the support (i.e. first layer, graphene layer structure and/or optional further layer of dielectric material of the first wafer, and/or the second layer and/or metal contacts of the second wafer). This may be done using conventional photolithography techniques and the like, and may also be used as described below to provide metal contacts. For example, the first wafer can be patterned before the wafer bonding step in order to pattern the graphene layer structure into desired device shapes (i.e. into an array of individual devices across the wafer) together with any further layers provided on the surface which preferably retains the same shape as the graphene thereby acting as a protective cap. The underlying first layer may optionally be patterned at this stage too, optionally into the same shape. Alternatively, as described in exemplary embodiments herein, such patterning may be performed after wafer bonding and removal of the silicon support, though, as will be appreciated, the first layer then becomes that “on” the graphene surface and any further layers that may have been deposited will underly the graphene layer structure in the resulting laminate (where viewed with the second layer and/or second support of the second wafer at the bottom of the resulting laminate).

The second layer of the second wafer may also be patterned before wafer bonding. In some preferred embodiments, the pattern is substantially the “negative” of the pattern of the first wafer in order to ensure conformal contact between the two patterned surfaces of the first and second wafers. Each wafer may further include patterning alignment markers in order to facilitate orientation and optical alignment of the two wafer surfaces for the subsequent wafer bonding step. In this way, complete device structures can be obtained without requiring further patterning after removal of the sacrificial first silicon support. As will be appreciated, further layers and/or further metal contacts may nevertheless be deposited and patterned (for example to provide a gate contact) after wafer bonding and removal of the silicon wafer.

The second wafer comprising exposed metal contacts may be used in embodiments which do not comprise the optional step of forming a further layer comprising dielectric material on the graphene layer structure so that the uppermost layer of the first wafer is the exposed graphene layer structure during the wafer bonding step that then contacts the metal contacts. However, there is a risk with damaging the graphene layer structure when the graphene layer structure is uppermost layer of the first wafer and is the exposed contact surface during wafer bonding.

It is therefore also particularly preferred in some embodiments to form metal contacts in contact with the graphene layer structure prior to wafer bonding, for example, in combination with the step of forming one or more further layers of dielectric material. Contacts may be deposited during the patterning step(s) (e.g. before or after patterning the graphene layer structure into the desired shape for a device).

The exposed surface of metal contacts on the first and/or second wafers may preferably be provided coplanar with the exposed surface of the surrounding material of the further dielectric layer (when present) and/or the second layer, respectively. Substantially flat layers are particularly preferred for wafer bonding in the absence of metal contacts in order to ensure good contact and bonding between the layers. Advantageously, complementary metal contacts (i.e. metal to metal) are typically simpler to bond together during a wafer bonding step (e.g. require lower temperatures and/or pressures which is advantageous to avoid undue damage to the other layers, and in particular the graphene layer structure). In other embodiments, the metal contacts of one of both wafers may protrude from the exposed uppermost surface. In such embodiments, for example where the graphene layer structure is exposed without having further layers of dielectric material formed thereon, the exposed surface is kept from contacting the surface of the second wafer avoiding the risk of damage. Typically, the difference in height between the metal contacts and the surface of the adjacent layers is less than 10 μm, more preferably less than 5 μm. The difference may also be at least 100 nm, at least 500 nm, or at least 1 μm.

Wafer-bonding processes are generally well-known. Preferably, the step of wafer-bonding is direct bonding (which may also be referred to a fusion bonding). Such processes are typically used to bond layers of, for example, two dielectric oxides and/or metal contacts whereby the process results in chemical bonds between the two surfaces as a result of the two surfaces having available bonding sites for hydrogen and/or covalent bonding, and being sufficiently clean and smooth. In some embodiments, the second layer is bonded to the exposed surface of the graphene layer structure, the resulting bonding being through Van der Waals forces.

Such a step may be carried out in a conventional wafer bonding apparatus. Typically, the process comprises heating the contacted wafers, optionally under application of a force. It is particularly preferred that the step is carried out under vacuum so as to exclude as far as possible any oxygen and/or moisture from the surface of the two wafers. The presence of oxygen-containing impurities risks contamination of the pristine graphene surface as well as hindering bonding. In a preferred embodiment, the wafer-bonding step is carried out directly after growth of the graphene layer structure whereby the first wafer is maintained under an inert atmosphere between the steps, or otherwise is maintained under an inert atmosphere whilst any further layers and/or metal contacts are deposited and patterned. Similarly, the second wafer may be maintained under an inert atmosphere immediately prior to wafer-bonding, for example when manufactured through deposition of the second layer on the second silicon support. Alternatively, the second wafer may be obtained commercially and subjected to an anneal to clean the surface prior to wafer-bonding.

Preferably, the wafer-bonding is performed at a temperature of from 100° C. to 850° C., preferably from 150° C. to 450° C., such as from 200° C. to 400° C. Lower temperatures are generally preferred when further layers are present, such as molybdenum oxide, since this reduces the risk of damaging the graphene and the further layer facilitates the wafer bonding. On the other hand, pristine graphene may require higher temperatures and vacuum in order to provide effective bonding. A force of at least 100 N, such as at least 500 N may be applied during wafer-bonding, and/or up to 10 kN in some embodiments.

There is no strict upper limit, though a maximum of 850° C. is preferred where the second wafer is a CMOS wafer. Typical second layers on second silicon supports (i.e. CMOS) include silicon oxide, silicon nitride, alumina, hafnia and the like, and as described herein, may also incorporate metal contacts exposed as the surface and metal vias embedded therein.

In some preferred embodiments, the second layer may be provided by, or include an uppermost sub-layer, formed of two-dimensional material for forming Van der Waals heterostructures. For example, the exposed contact surface of the second layer may be provided by h-BN, a transition metal dichalcogenide (TMDC) or a further graphene layer structure, preferably h-BN since this material has little influence on the electronic properties of the graphene layer structure. Where the exposed contact surface is provided by a graphene layer structure, particularly a graphene monolayer, wafer-bonding as described herein may be used to bond a further graphene monolayer. Accordingly, there is described herein an embodiment wherein the first and second wafers are substantially identical and comprise a graphene monolayer and the resulting laminate comprises a graphene bilayer. The process of the present invention allows for the graphene monolayers to be aligned easily, and in particular at a twisted angle of about 1.1° (i.e. to provide a stable sandwiched twisted bilayer graphene); such an angle is known to provide further unique electronic properties in bilayer graphene.

The method further comprises a step of removing the first silicon support, and optionally a portion of the first layer, to leave a retained portion of the first layer formed from the first region and having a thickness of less than 20 nm.

Generally, the method comprises chemically etching the first silicon support so as to remove the silicon and expose the dielectric layer. Any conventional silicon etchant may be used, for example hydrogen fluoride, nitric acid, an alkali metal hydroxide, ethylenediamine pyrocatechol or tetramethylammonium hydroxide, preferably sodium or potassium hydroxide. As will be appreciated, such etchants may be used in any typical formulation and solvent (e.g. water or an alcohol such as methanol, ethanol or isopropanol). Such a process may be referred to as “wet etching”. The first layer being formed of a dielectric material is resistant to etching by the etchant. The method optionally comprises removing a portion of the first layer (which will be appreciated to be that portion distal to the first region described herein). Preferably, the portion of the first layer is removed by reactive ion etching.

Preferably, removing the first silicon support comprises grinding, and may be used in combination with, and prior to, chemical etching such that removal of all of the silicon support is completed by chemical etching. Grinding is typically much faster than chemical etching and more suitable for removing the initial portion of the support at the greater initial thickness. The support may be thinned by grinding so as to remove from 70 to 99% of the silicon support, for example, followed by chemical etching.

Preferably the retained portion of the first layer has a thickness of less than 10 nm, preferably less than 5 nm. Preferably, the retained portion has a thickness of at least 2 nm. Preferably the first region of the first layer has a thickness that is equal to or greater than the thickness of the retained portion of the first layer. Therefore, the entirety of the retained region may be formed from the first region of the first layer which has the advantageously low dislocation density. As such, the inventors were surprised to find that the present method allows for the formation of a graphene-containing laminate which comprises a dielectric layer having a greater crystalline quality that that which may be grown by other conventional methods, specifically when combined with the quality of graphene that is obtained by direct growth by CVD.

In a further aspect, the present invention relates to a graphene-containing laminate comprising, in order:
(i) a support (preferably silicon);
(ii) a primary dielectric layer;
(iii) a graphene layer structure;
(iv) a secondary dielectric layer having a thickness of less than 20 nm and wherein the secondary dielectric layer satisfies the following:
   a) a dislocation density of less than 5,000 cm−2 as measured by TEM; and
   b) a surface roughness (Ra) of less than 1 nm as measured by AFM;
wherein, optionally, there is further provided one or more further dielectric layers between the primary dielectric layer and the graphene layer structure.

The graphene having been grown by CVD directly on the secondary dielectric layer therefore avoids physical transfer processing. The physical transfer of graphene, usually from copper substrates, introduces numerous defects which negatively impacts the physical and electronic properties of graphene. As such, a person skilled in the art can readily ascertain whether a graphene layer structure, and by extension a graphene-containing laminate is one comprising a CVD-grown graphene layer structure that has been grown directly on the specific materials using conventional techniques in the art such as AFM and energy dispersive X-ray (EDX) spectroscopy. The graphene layer structure is devoid of metal, in particular copper, contamination and devoid of organic polymer residues by virtue of the complete absence of these materials in the process of obtaining the graphene-containing laminate. Furthermore, such processing is not suitable for large scale manufacture (such as on CMOS substrates in fabrication plants). Unintentional doping, particularly from the catalytic metal substrates together with the etching solutions, also results in the production of graphene which is not sufficiently consistent from sample to sample as is required for commercial production of electronic devices.

In another aspect, the present invention provides a graphene-containing laminate comprising, in order:
(i) a support (preferably silicon);
(ii) a primary dielectric layer;
(iii) a graphene layer structure; and
(iv) a secondary dielectric layer having a thickness of less than 20 nm and wherein the secondary dielectric layer having a dislocation density of less than 5,000 cm⁻² as measured by TEM;
wherein, the second dielectric layer is formed of aluminium nitride, magnesium fluoride, calcium fluoride, yttria-stabilised zirconia (YSZ), yttria-stabilised hafnia (YSH) and/or rare-earth oxide (preferably scandium oxide); and
wherein, optionally, there is further provided one or more further dielectric layers between the primary dielectric layer and the graphene layer structure.

Optional further layers, such a molybdenum oxide, may have been used during manufacture to counter dope the CVD-grown graphene to have a final charge carrier concentration of less than 5×10¹² cm−2 after wafer bonding and etching of the sacrificial silicon support to expose the secondary dielectric layer.

The laminate is especially advantageous for the manufacture of electronic devices since the inventors have found that the method described herein allows for such a product comprising graphene having the quality obtained by direct CVD growth, together with a dielectric layer thereon which can be surprisingly thin yet still exhibit an exceedingly low dislocation density which would not be achievable through direct growth on CVD quality graphene. Preferably, the laminate consists of the layers described.

The manufacturing method described herein leads to a unique laminate, in particular one in which the secondary dielectric layer has a dislocation density of less than 5,000cm⁻² , and such characteristics, a result of being obtainable by the method, would not be observed in other manufacturing methods (e.g. those which involve forming the layer on graphene).

The dislocation density of less than 5,000 cm⁻² will be appreciated as characterising a region of at least 2 nm extending directly from the graphene layer structure of the laminate. Preferably, the region extends at least 10 nm from the graphene layer structure. Similarly, it will be appreciated that the surface roughness refers to the surface which is contact with the graphene layer structure.

In a further aspect, the present invention relates to an electronic device comprising the graphene-containing laminate described herein (i.e. that of the further aspect of the invention and/or obtainable by the method of the first aspect).

In a further aspect of the present invention, there is provided an electronic device comprising the graphene-containing laminate described herein. That is, an electronic device may be formed using the method disclosed herein, or the resulting graphene-containing laminate, using conventional techniques to pattern and etch the layers as desired and to deposit contacts for connection into an electronic circuit (such as via metal wires). As will be appreciated, a large-area graphene-containing laminate (i.e. a wafer such as one having a diameter of greater than or equal to 5 cm (2 inches)) may be processed to manufacture an array of electronic devices on the common underlying support (that of the second silicon support described with respect to the method of manufacture). This may then be diced into individual devices such that an electronic device comprises a portion of a larger graphene-containing laminate. Thin devices may be manufactured therefrom through grinding and/or etching of the silicon support.

Typically, contacts are metal contacts, such as those formed of chromium, titanium, aluminium, nickel and/or gold. Generally contacts are provided in contact with a surface and/or an edge of the graphene layer structure of the graphene-containing laminate.

The architecture provided by the laminated structure of a silicon support having thereon a primary dielectric, graphene and a secondary dielectric is particularly suitable for incorporation into transistors and the like. However, through appropriate further processing the laminate may also be used to manufacture other devices such as capacitors, electro-optic devices, and diodes (including LEDs and solar cells as well as resonant tunnelling diodes).

Preferably the electronic device is a top-gated electronic device wherein a gate contact is provided on a surface of the secondary dielectric layer distal from the graphene layer structure. As will be appreciated in a vertical device configuration, the gate contact is provided over the graphene in order to modulate the electronic properties of the graphene (through the dielectric layer). The retained region of the first layer as described in the method above provides the secondary dielectric layer of the laminate according to this further aspect. As such, a top-gated electronic device such as a transistor employs this high-quality dielectric material as a gate dielectric which allows for an improvement in device performance without requiring other interfacial layers between the graphene and the gate.

In some embodiments, the silicon support may be reduced in thickness or removed completely after forming the electronic device from the laminate described herein such that the present invention also provides an electronic device comprising a graphene-containing laminate comprising, in order:
(i) an optional silicon support;
(ii) a primary dielectric layer;
(iii) a graphene layer structure; and
(iv) a secondary dielectric layer having a thickness of less than 20 nm and wherein the secondary dielectric layer satisfies the following:
   a) a dislocation density of less than 5,000 cm⁻² as measured by TEM; and
   b) a surface roughness (Ra) of less than 1 nm as measured by AFM;
wherein, optionally, there is further provided one or more further dielectric layers between the primary dielectric layer and the graphene layer structure.

### Figures

The present invention will now be described further with reference to the following exemplary and non-limiting Figures, in which:

FIG. 1 illustrates an embodiment of a method according to the present invention.

FIG. 2 is a cross-section of an embodiment of a first wafer prior to the step of wafer-bonding.

FIG. 3 is a cross-section of an embodiment of a top-gated transistor comprising a graphene-containing laminate according to the present invention.

FIG. 4 is a cross-section of an embodiment of a top-gated barristor comprising a graphene-containing laminate according to the present invention.

FIG. 5 is a cross-section of an embodiment of an electro-optic modulator comprising a graphene-containing laminate according to the present invention.

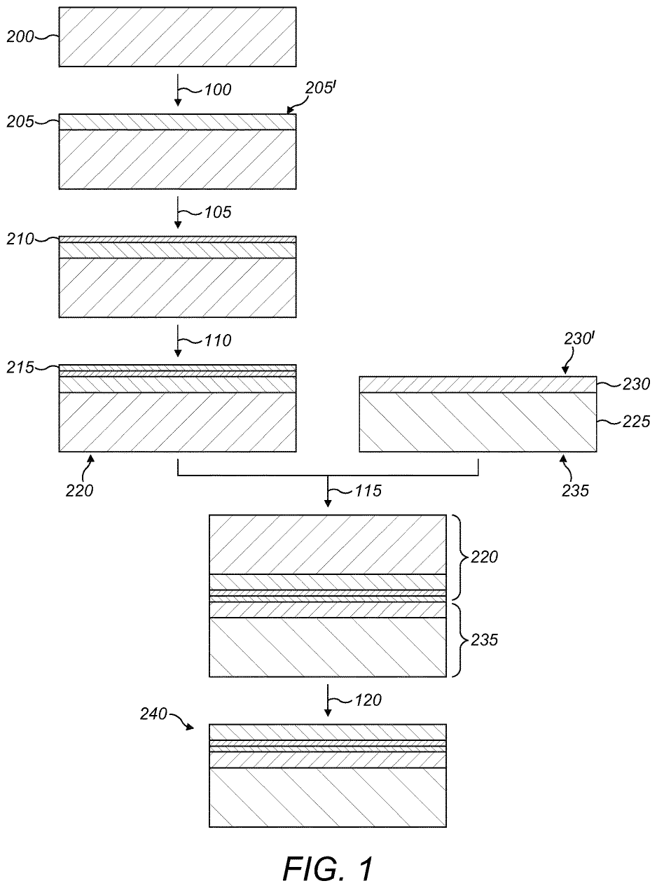

FIG. 1 illustrates an exemplary method for the manufacture of a graphene-containing laminate, with each step shown in cross-section.

In a first step 100, a commercially available silicon support 200 (i.e. a substrate/wafer) having a diameter of at least 5 cm is provided and a first layer 205, for example consisting essentially of scandium oxide, is formed on a surface of the silicon support 200 by molecular beam epitaxy.

The first layer 205 is grown in step 100 to a thickness of between 5 nm and 50 nm resulting in an exposed surface 205′ that is distal from the silicon support 200 (i.e. as opposed to the surface of the first layer 205 that interfaces the silicon support 200). The first layer 205 comprises a first region that extends at least 2 nm down from the exposed growth surface 205′, and may extend the full thickness of the first layer 205. The first layer 205 is characterised by a dislocation density of less than 5,000 cm⁻² as measured by TEM and a surface roughness (Ra) of less than 1 nm as measured by AFM. Together, the first layer 205 and the silicon support 200 may be referred to as a first wafer 220. In a second step 105, a graphene monolayer 210 is grown on the exposed growth surface 205′ in an MOCVD reactor and in a third step 110, a further layer 215 is formed on the exposed surface of the graphene monolayer 210. The further layer may be selected to dope the graphene monolayer 210 so as to counter dope the intrinsic doping resulting from CVD growth. Preferably, the further layer 215 is formed of molybdenum oxide having a thickness of up to about 5 nm. Together, the silicon support 200, the first layer 205 and the graphene monolayer 210 and further layer 215 may also be referred to as a first wafer 220 for the wafer-bonding step.

The method further comprises providing a second wafer 235 for the wafer-bonding. In the present embodiment, the second wafer 235 is a conventional silicon-on-insulator wafer comprising a (second) silicon support 225 having a layer of silicon oxide 230 thereon which has an exposed contact surface 230′. The silicon oxide layer 230 typically has a thickness of many tens to hundreds of nm.

In a fourth step 115, the first wafer 220 and the second wafer 235 are directly wafer-bonded by contacting the surface of the further layer 215 with the exposed contact surface 230′ of the silicon oxide layer 230. As a result, the graphene monolayer 210 is sandwiched between the (first) silicon support 200 and the silicon oxide 230 (and the (second) silicon support 225). Such a step is carried out in vacuum under the application of a small force and up to about 400° C.

In a fifth step 120, the (first) silicon support 200 is removed by first wafer grinding to remove a majority of the silicon support 200 and then by chemically etching with an aqueous solution of an alkali metal hydroxide thereby exposing a surface of the first layer 205 (i.e. that surface which interfaced the silicon support 200) forming a graphene-containing laminate 240. The first layer 205 may be etched in order to reduce its thickness, for example to 10 nm or less, by reactive ion etching. The quality of the first layer 205 of the laminate 240 is advantageously much greater than that which may be formed on directly grown CVD graphene such that a thinner layer can be used in electronic devices as a dielectric layer between graphene and contacts/electrodes. FIGS. 3-5 illustrate examples of such devices. In some embodiments, the (second) silicon support 225 may be reduced in thickness or removed completely, for example after forming the electronic device (i.e. after forming any further layers, contacts and patterning).

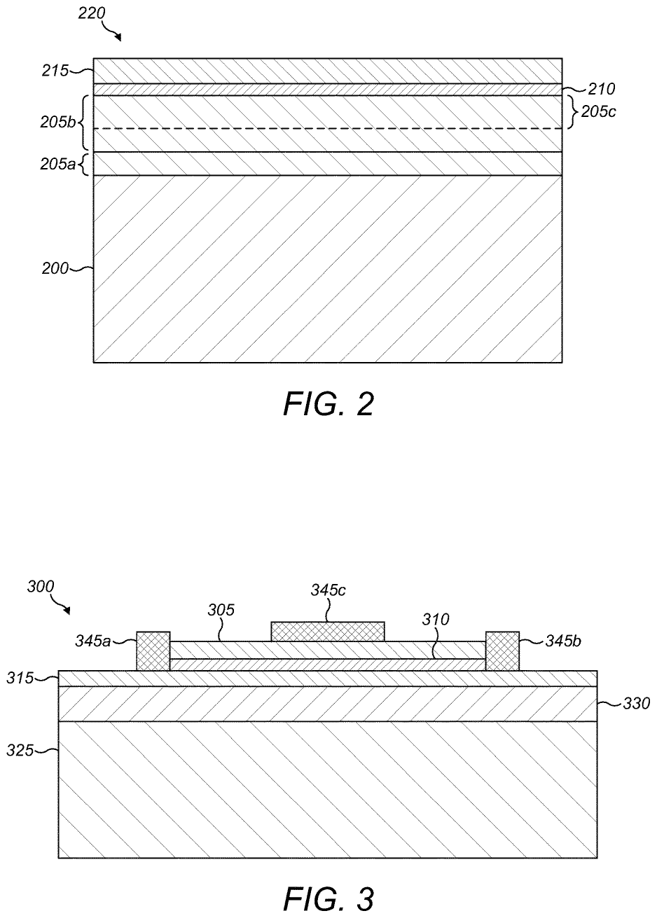

FIG. 2 is a cross-section of an exemplary first wafer 220 that may be used in the method of the present invention, for example the method illustrated in FIG. 1. The first wafer 220 comprises a silicon support 200 and a first layer 205 thereon formed of a first sub-layer 205a and a second sub-Layer 205b.

The first sub-layer 205a of the first layer 205 may be a buffer oxide layer which may be used to reduce the defects in the dielectric layers formed thereon by minimising the lattice constant mismatch to the silicon support 200. In an example, the first sub-layer is formed of yttrium oxide, which may have a thickness of 5 nm or less.

The second sub-layer 205b may be formed of yttria-stabilised zirconia (YSZ), yttria-stabilised hafnia (YSH) or a rare-earth oxide, for example. The second sub-layer may have a thickness of about 5 nm or more and provides the first region 205c of the first layer 205 in which the first region 205c is characterised by a dislocation density of less than 5,000 cm⁻² as measured by TEM and a surface roughness (Ra) of less than 1 nm as measured by AFM. The first wafer 220 further comprises the graphene monolayer 210 on the first region 205c, and a further layer 215 on the graphene monolayer 210.

FIG. 3 is a cross-section of an exemplary top-gated transistor 300 comprising a graphene-containing laminate according to the present invention. The transistor 300 is formed of a silicon support 325 and a layer of silicon oxide 330 (which may have originated from a second wafer 235 for example). On the silicon oxide layer there is a (primary) layer of dielectric material 315, for example molybdenum oxide which together with a (secondary) layer of dielectric material 305 sandwiches (i.e. directly) a monolayer of graphene 310 therebetween. The secondary dielectric layer 305 has been patterned together with the graphene monolayer 310 so as to share a continuous edge (i.e. have the same shape).

The transistor 300 further comprises first and second electrical contacts 345a, 345b which have been deposited in contact with opposing edges of the graphene monolayer 310. For example, for a transistor, the graphene monolayer 310 may have a rectangular shape with such contacts 345a, 345b provided in contact with the opposing shorter edges. These contacts can serve as source and drain contacts.

The transistor 300 further comprises a third electrical contact 345c on the secondary dielectric layer 305 as a gate contact. The quality of the secondary dielectric layer, in particular having a dislocation density of less than 5,000 cm⁻² as measured by TEM, allows for the thickness of be very thin, such as 5 nm or less, which in turn allows for improved modulation of current between source and drain by the gate contact (i.e. improved device performance).

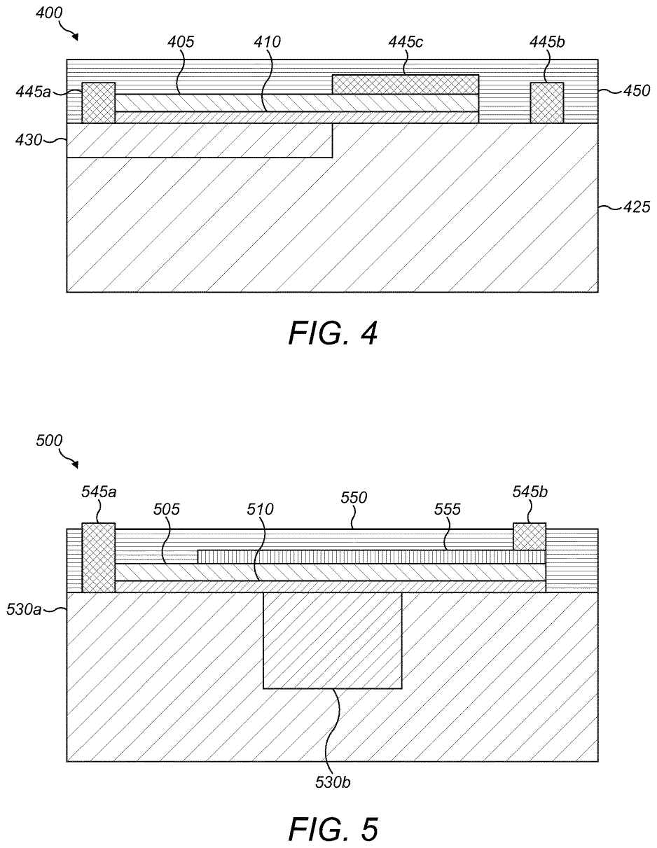

FIG. 4 is a cross-section of an exemplary top-gated barristor 400 comprising a graphene-containing laminate according to the present invention. The barristor 400 shares many similarities with transistor 300 and may be formed of substantially the same materials.

One difference is that the silicon support 425 comprises an embedded region of primary dielectric material 430, for example silicon dioxide. The graphene monolayer 410 is patterned together with the secondary dielectric material 405 to reside on and across the surface of the primary dielectric 430 and silicon support 425. A first electrical contact 445a (e.g. a source contact) is provided in contact with an edge of the graphene monolayer on the region of the underlying substrate comprising the dielectric material 430. A second electrical contact 445b (e.g. a drain contact) is provided on the silicon support separated from the graphene monolayer. The second contact 445b may be separated by a distance of at least 2 nm, preferably at least 5 nm and the region therebetween filled with a dielectric coating 450. The dielectric coating 450 may be an ALD layer of aluminium oxide, for example.

A third electric contact 445c is provided on the secondary dielectric layer over and across the entire region of the underlying graphene monolayer 410 which is on the semiconducting silicon support 425. As such, the interface between the graphene monolayer 210 and the silicon support 425 provides a barrier to current flow which may be modulated by the overlying third electrical contact 445c. Such an arrangement may be used to improve current on/off ratios.

FIG. 5 is a cross-section of an exemplary electro-optic modulator 500 comprising a graphene-containing laminate according to the present invention. The modulator 500 comprises a primary dielectric layer 530 formed of a silicon dioxide layer 530a having embedded therein a channel of waveguide material 530b, for example formed of silicon nitride. The silicon dioxide layer 530a is also provided on an underlying silicon support (not shown).

The graphene monolayer 510 is patterned together with the secondary dielectric material 505 to reside on and across the width of the waveguide 530b and adjacent regions of the silicon dioxide layer 530a. The modulator 500 further comprises a second electrode 555, which may be formed of indium tin oxide (ITO), for example, which extends over and across the width of the underlying waveguide 530b. First and second electrical contacts 545a, 545b are provided in contact with the graphene monolayer 510 and second electrode 555, respectively. The graphene monolayer 510 and second electrode 555 serve as electrodes which may be used to modulate the transmittance of light through the waveguide 530b (i.e. in a direction orthogonal to the cross-section illustrated). The electrodes may be coated with a dielectric coating 550 such as an ALD layer of aluminium oxide.

As used herein, the singular form of “a”, “an” and “the” include plural references unless the context clearly dictates otherwise. The use of the term “comprising” is intended to be interpreted as including such features but not excluding other features and is also intended to include the option of the features necessarily being limited to those described. In other words, the term also includes the limitations of “consisting essentially of” (intended to mean that specific further components can be present provided they do not materially affect the essential characteristic of the described feature) and “consisting of” (intended to mean that no other feature may be included such that if the components were expressed as percentages by their proportions, these would add up to 100%, whilst accounting for any unavoidable impurities), unless the context clearly dictates otherwise.

It will be understood that, although the terms “first”, “second”, etc. may be used herein to describe various elements, layers and/or portions, the elements, layers and/or portions should not be limited by these terms. These terms are only used to distinguish one element, layer or portion from another, or a further, element, layer or portion. It will be understood that the term “on” is intended to mean “directly on” such that there are no intervening layers between one material being said to be “on” another material. Spatially relative terms, such as “under”, “below”, “beneath”, “lower”, “over”, “above”, “upper” and the like, may be used herein for ease of description to describe one element or feature's relationship to another element(s) or feature(s). It will be understood that the spatially relative terms are intended to encompass different orientations of the device in use or operation in addition to the orientation depicted in the figures. For example, if a device as described herein is turned over, elements described as “under” or “below” other elements or features would then be oriented “over” or “above” the other elements or features. Thus, the example term “under” can encompass both an orientation of over and under. The device may be otherwise oriented and the spatially relative descriptors used herein interpreted accordingly.

The foregoing detailed description has been provided by way of explanation and illustration, and is not intended to limit the scope of the appended claims. Many variations of the presently preferred embodiments illustrated herein will be apparent to one of ordinary skill in the art, and remain within the scope of the appended claims and their equivalents.

1. A method for the manufacture of a graphene-containing laminate, the method comprising:
(i) providing a first wafer comprising a first layer on a first silicon support, wherein the first layer is a crystalline dielectric layer and has an exposed growth surface distal from the first silicon support, wherein the first layer has a first region extending at least 2 nm down from the exposed growth surface, wherein the first region satisfies the following:
a) a dislocation density of less than 5,000 cm⁻² as measured by TEM; and
b) a surface roughness (Ra) of less than 1 nm as measured by AFM;
(ii) providing a second wafer comprising a second layer, wherein the second layer has an exposed contact surface;
(iii) forming a graphene layer structure on the exposed growth surface of the first layer by CVD, and optionally forming a further layer comprising dielectric material on the graphene layer structure;
(iv) wafer-bonding the first wafer to the exposed contact surface of the second layer to sandwich the graphene layer structure between the first silicon support and the second layer; and
(v) removing the first silicon support, and optionally a portion of the first layer, to leave a retained portion of the first layer formed from the first region and having a thickness of less than 20 nm.

2. The method according to claim 1, wherein the wafer-bonding is performed at a temperature of from 100° C. to 850° C.

3. The method according to claim 1, wherein the second wafer comprising the second layer further comprises a second silicon support, wherein the exposed contact surface of the second layer is distal from the second silicon support.

4. The method according to claim 1, wherein the second layer is a second dielectric layer.

5. The method according to claim 1, wherein the further layer comprises one or more sub-layers.

6. The method according to claim 1, wherein the further layer comprises a dielectric metal oxide.

7. The method according to claim 6, wherein the further layer consists of a molybdenum oxide layer having a thickness of less than 5 nm.

8. (canceled)

9. The method according to claim 1, wherein the first region of the first layer extends at least 5 nm down from the exposed growth surface.

10. The method according to claim 1, wherein the retained portion of the first layer has a thickness of less than 10 nm.

11. The method according to claim 1, wherein the first region of the first layer has a thickness that is equal to or greater than the thickness of the retained portion of the first layer.

12. (canceled)

13. The method according to claim 1, wherein the growth surface has a <111> crystallographic orientation.

14. The method according to claim 1, wherein the first region of the first layer is formed of aluminium nitride, magnesium fluoride, calcium fluoride, yttria-stabilised zirconia (YSZ), yttria-stabilised hafnia (YSH) and/or rare-earth oxide.

15. The method according to claim 1, wherein the first layer comprises a buffer layer directly on the first silicon support.

16. The method according to claim 1, wherein the first layer is formed by molecular beam epitaxy and/or high temperature sputtering.

17. The method according to claim 1, wherein the step of removing the first silicon support comprises grinding and/or chemical etching.

18. The method according to claim 17, wherein the step of removing the first silicon support is completed by chemical etching, and the portion of the first layer is removed by reactive ion etching.

19. The method according to claim 1, wherein the temperature of the growth surface during CVD is from 700° C. to 1350° C.

20. (canceled)

21. (canceled)

22. (canceled)

23. A graphene-containing laminate comprising, in order:
(i) a support;
(ii) a primary dielectric layer;
(iii) a graphene layer structure; and
(iv) a crystalline secondary dielectric layer having a thickness of less than 20 nm and wherein the secondary dielectric layer satisfies the following:
a) a dislocation density of less than 5,000 cm⁻² as measured by TEM; and
b) a surface roughness (Ra) of less than 1 nm as measured by AFM;
wherein, optionally, there is further provided one or more further dielectric layers between the primary dielectric layer and the graphene layer structure.

24. An electronic device comprising the graphene-containing laminate according to claim 23.

25. The electronic device according to claim 24, wherein the electronic device is a top-gated electronic device wherein a gate contact is provided on a surface of the secondary dielectric layer distal from the graphene layer structure.
